(19) United States
(12) Patent Application Publication
(10) Pub. No.: US 2021/0035648 A1
(43) Pub. Date: Feb. 4, 2021

(54) STORAGE SYSTEM WITH ERROR MITIGATION MECHANISM AND METHOD OF OPERATION THEREOF

(71) Applicant: CNEX LABS, Inc., San Jose, CA (US)

(72) Inventors: Jun Tao, Ladera Ranch, CA (US); Chih-Chieng Cheng, Cupertino, CA (US); Shanying Luo, Fremont, CA (US)

(21) Appl. No.: 16/530,357

(22) Filed: Aug. 2, 2019

(51) Int. Cl. G11C 16/34; G06F 3/06; G11C 16/26; G11C 11/56

(52) U.S. Cl. CPC G11C 16/3404; G06F 3/0619; G06F 3/064; G11C 11/5671; G06F 3/0679; G11C 16/26; G11C 11/5642; G06F 3/0659

(57) ABSTRACT

A storage system includes: a control processor, configured to: read user data with a read threshold, detect a correctable data error in the user data, adjust the read threshold to correct the correctable data error, read a 1 and 0 counter to determine which threshold adjustment range has been activated, generate an adjusted read threshold, based on the threshold adjustment range, to update an optimal read threshold set; and read the user data in a physical block using the adjusted read threshold.

### TECHNICAL FIELD

An embodiment of the present invention relates generally to a storage system, and more particularly to a system for error mitigation.

### BACKGROUND

Non-volatile memory, such as NAND flash, has driven massive increases in capacity and verification processes to support intelligent devices. In order to reduce the cost per gigabyte nonvolatile memories, these devices have become denser by packing more data in the same silicon area, by scaling the size of the flash cells, adding three dimensional arrays of storage cells, and storing more bits in each of them. However, the changes in cell-size and storage cell configuration has come at the cost of impaired read back reliability. As read recovery retries increase, performance can be adversely impacted and system performance degraded.

Thus, a need still remains for a storage system with error mitigation mechanism to provide improved data reliability and minimize read access times. In view of the ever-increasing commercial competitive pressures, along with growing consumer expectations and the diminishing opportunities for meaningful product differentiation in the marketplace, it is increasingly critical that answers be found to these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides an apparatus, including a control processor, configured to: read user data with a read threshold, detect a correctable data error in the user data, adjust the read threshold to correct the correctable data error, read a 1 and 0 counter to determine which threshold adjustment range has been activated, generate an adjusted read threshold, based on the threshold adjustment range, to update an optimal read threshold set; and read the user data in a physical block using the adjusted read threshold.

An embodiment of the present invention provides a method including reading user data from a non-volatile memory array using a read threshold; detecting a correctable data error in the user data; adjusting the read threshold to correct the correctable data error; reading a 1 and 0 counter for determining which threshold adjustment range has been activated; generating an adjusted read threshold, based on the threshold adjustment range, for updating an optimal read threshold set; and reading the user data in the physical block using the adjusted read threshold.

An embodiment of the present invention provides a non-transitory computer readable medium including instructions for execution including: including reading user data from a non-volatile memory array using a read threshold; detecting a correctable data error in the user data; adjusting the read threshold to correct the correctable data error; reading a 1 and 0 counter for determining which threshold adjustment range has been activated; generating an adjusted read threshold, based on the threshold adjustment range, for updating an optimal read threshold set; and reading the user data in the physical block using the adjusted read threshold.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a block diagram of a storage system with error mitigation mechanism in an embodiment of the present invention.

FIG. 2 depicts a functional block diagram of a 1 and 0 counter in an embodiment.

FIG. 3 is a graphical view of an exemplary access of a cell of a non-volatile memory.

FIG. 4 is a graphical view of an exemplary access of a cell of the non-volatile storage array.

FIG. 5 is an operational flow diagram of the storage system with error mitigation mechanism in an embodiment of the present invention.

FIG. 6 is a flow chart of a method of operation of a storage system in an embodiment of the present invention.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

The term “module” referred to herein can include hardware or hardware supported by software in an embodiment of the present invention in accordance with the context in which the term is used. For example, the software can be machine code, firmware, embedded code, and application software. Also for example, the hardware can be circuitry, processor, computer, integrated circuit, integrated circuit cores, application specific integrated circuit (ASIC), passive devices, or a combination thereof.

As an example, one method to reduce the time spent in error recovery is to apply a read threshold mechanism to predict the optimum read threshold of a storage page and adjust it for the usable storage before the errors become unrecoverable. The term “error mitigation” referred to herein can include proactively making adjustments to the read channel in order to avoid errors that would normally have occurred had the adjustments not been made. The term “plane” referred to herein can be defined as an integrated circuit memory device or a separately regulated portion of the integrated circuit memory device that can have multiple of the separately regulated portion.

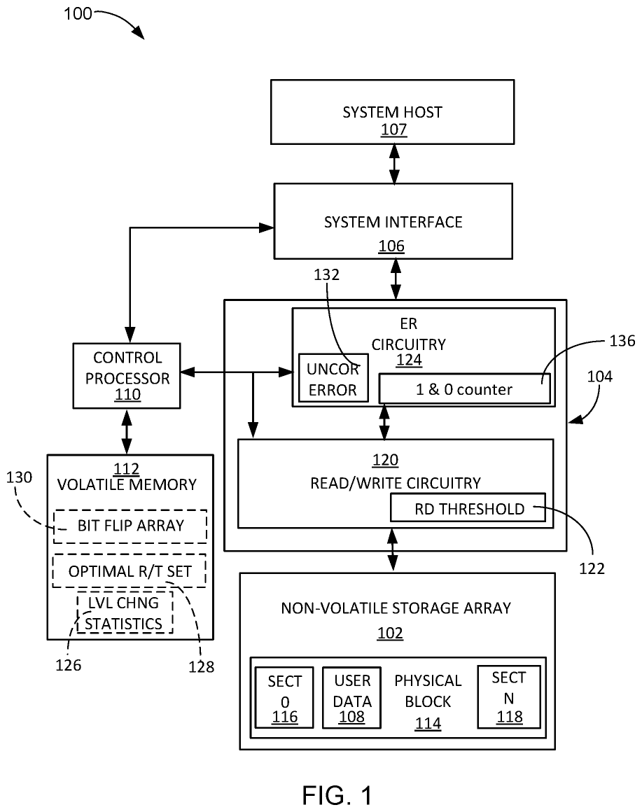

Referring now to FIG. 1, therein is shown a functional block diagram of a storage system 100 with error mitigation mechanism in an embodiment of the present invention. The functional block diagram of the storage system 100 depicts a non-volatile memory array 102 coupled to a read/write channel 104. A system interface 106 transfers user data 108 to and from the non-volatile memory array 102. The system interface 106 can execute the movement of the user data 108 into and out of the storage system 100. As an example, the system interface 106 can transfer user data 108 through the read/write channel 104 for storage to and retrieval from the non-volatile memory array 102.

The non-volatile memory array 102 can include multiple integrated circuit die, multiple planes within the multiple integrated circuit die, or a combination thereof, for the purpose of storing and accessing the user data 108 provided through the system interface 106. The non-volatile memory array 102 can include any number of non-volatile memory integrated circuits capable of storing multiple bits per cell, such as multi-level cell (MLC), triple-level cell (TLC), quad-level cell (QLC), or the like. The system interface 106 can communicate with a system host 107 through one or more interface protocols, such as a universal serial bus (USB), a multi-media card (MMC), a peripheral component interconnect express (PCI-E), a small computer system interface (SCSI), a serial-attached SCSI (SAS), a serial advanced technology attachment (SATA), a parallel advanced technology attachment (PATA), an enhanced small disk interface (ESDI), and an integrated drive electronics (IDE).

The read/write channel 104 can be a hardware structure that can be supported by software, to encode and decode the user data 108 for storage in the non-volatile memory array 102. The read/write channel 104 can also generate error correction data and perform error correction of the user data 108 read from the non-volatile memory array 102. The user data 108 can be program data or input data stored in the non-volatile memory array 102 for later execution or processing.

A control processor 110 can provide at least a portion of the computation resource for the storage system 100. For example, the control processor 110 can be a processor, an application specific integrated circuit (ASIC), an embedded processor, a microprocessor, a hardware control logic, a hardware finite state machine (FSM), a digital signal processor (DSP), or a combination thereof. The control processor 110 can coordinate the operation of the storage system 100. As an example, the control processor 110 can be coupled to the system interface 106, the read/write channel 104, and a volatile memory 112.

The volatile memory 112 provides at least a portion of the storage of information for the storage system 100. As examples, the volatile memory 112 can be a volatile memory array, such as a matrix of interconnected volatile memory integrated circuits including dynamic random access memory (DRAM), static random access memory (SRAM), register files, non-volatile memory, or a combination thereof, coupled to the control processor 110.

The system interface 106 can be supported by the control processor 110. The control processor 110 can be implemented with hardware circuitry in a number of different manners. The system interface 106 can be implemented as a hardware control logic, a hardware finite state machine (FSM), or a programmable bus controller, that can provide data transport between the non-volatile memory array 102 and a system host 107.

The system host 107 can be a computer, a processor, a processor core, a device controller, or a combination thereof configured to generate, store, and retrieve the user data 108. The host system 107 can be directly coupled to the system interface 106, or it can be attached through a local bus, a local area network (LAN), or wide area network (WAN).

The non-volatile memory array 102 can also include a remote resource, such as a NAND flash-based network attached storage (NAS), storage area network (SAN), or a combination thereof. The cells in the non-volatile memory array 102 are organized into a plurality of super blocks 114. Each of the super blocks 114 can contain data pages from page 0 116 through page N 118, with each of the page 0 116 through the page N 118 written on a separate integrated memory device or a plane in the integrated memory device. Where the page can be a read/write unit page, a physical page, a word line, or a physical block within an integrated memory device or a plane within the integrated memory device.

The read/write channel 104 can be a hardware structure that can be supported by software, to encode and decode the user data 108 for storage in the non-volatile memory array 102. A read/write circuitry 120 can manage the writing to the sector 0 116 through sector N 118. During the reading of the user data 108, the read/write circuitry 120 can manipulate a read threshold 122 in order to adjust for errors detected by an error recovery (ER) circuitry 124. The control processor 110 can collect a count of the read data level changes as the read threshold 122 is changed. The control processor 110 can maintain the count of level change statistics 126 indicating that a bit flip in the user data 108 caused by a level change has occurred on any of the read thresholds 122, which can be stored in the volatile memory 112.

The control processor 110 can adjust the read threshold 122, of the sector 0 116 through sector N 118, based on the read threshold mechanism of the level change statistics 126, such as the bit flip count or information indicating a change in the data level between adjacent values of the read threshold 122, in order to maintain the operational performance of the currently addressed sector in the physical block 114.

The control processor 110 can manage the operation of the read/write channel 104 including performing calculations, optimizing the read threshold 122, and execution of interface commands delivered from the host system 107. The control processor 110 can provide the level change statistics 126 when reading the user data 108. The ER circuitry 124 can be a hardware structure used to encode intended or targeted data for providing error protection, error detection, error correction, redundancy, or a combination thereof.

The ER circuitry 124 can include a 1 and 0 counter 136. The 1 and 0 counter 136 can be a hardware structure that can monitor the state of the individual data bits of the selected one of the sector 0 116 through sector N 118 while processing the read data. During the analysis of the read threshold 122, the control processor 110 can read the user data 108, without enabling the ER circuitry 124 to perform error correction on the data, in order to capture each instance of a level change in the user data 108. The control processor 110 can also read the output of the 1 and 0 counter 136 to determine whether the last read attempt provided a balanced number of 1's and 0's in the data pattern or a range of offset exists in the difference between the number of 1's and 0's.

The read threshold 122 is defined as a selectable voltage reference used when reading the stored value in the sector 0 116 through sector N 118. The read threshold 122 can provide the voltage reference in incremental steps. By way of an example, the read threshold can have 128 linear steps that set the reference voltage for each of the design point voltage levels for the ideal read-back cell. The TLC NAND will have 7 major bit thresholds, {A, B, C, D, E, F, G}. The 128 steps available can be centered on each of the 7 major thresholds. This can be compared to QLC NAND, which has 15 major thresholds, and 128 steps applied to each.

It is understood that the read of any of the sector 0 116 through sector N 118 using each of the possible settings of the read threshold 122, can subject the selected one of the sector 0 116 through sector N 118 to hundreds or thousands of read operations. The full analysis of the read threshold 122 can further damage an already impaired version of the sector 0 116 through sector N 118 due to the reads depleting the charge of the stored data. This situation can be mitigated by maintaining an optimal value of the read threshold 122 for the physical page or plane in the physical block 114.

The storage system 100 can generate an optimal read threshold set 128 by performing multiple reads of the user data 108 with stepped values of the read threshold 122. Between reads the read threshold 122 can be incremented and the resulting data compared. By detecting and logging the number of bits that change value on each incremental step, a bit flip array 130 can be constructed. The bit flip array can be a matrix of the number of level changes counted for each selected offset step count for each of the read threshold 122 {A, B, C, D, E, F, G}. The control processor 110 can search the bit flip array 130 for the offset values that represents the minimum number of changed bits for each of the read threshold 122 {A, B, C, D, E, F, G}. These offset values represent the optimal read threshold set 128, which can provide the best possibility of correctly reading the user data 108 without detecting an uncorrectable error 132. It is understood that the uncorrectable error 132 is a data error that contains too many bit errors for the ER circuitry 124 to correct the user data 108 without additional read processing.

A large number of program and erase (P/E) cycles can cause the voltage of the cells holding the user data 108 to deviate from expected ranges after programming. Read disturbs, which refers to a significant amount of read operation on the sector 0 116 through sector N 118 of the physical block 114, will also cause the physical block 114 to shift to a higher voltage range. Therefore, it is extremely critical to calculate the optimal read threshold set 128, which provide the smallest number of read errors.

As the sector 0 116 through sector N 118 are repeatedly accessed, the voltage level of the user data 108 can shift making the valid settings for the read threshold 122 change over time. It is understood that the read threshold 122 can be adjusted dynamically based on the level change statistics 126 detected by the ER circuitry 124. The detection of the uncorrectable error 132 can cause the regeneration of the bit flip array 130 and selection of a new set of the optimal read threshold set 128 in order to better read the non-volatile memory array 102. In order to alleviate the additional number of reads required to correct the data read from and of the sector 0 116 through sector N 118, the control processor 110 can monitor the 1 and 0 counter to determine whether there is a balance in the data pattern.

For illustrative purposes, the storage system 100 will be described as utilizing the error correction mechanism in storing and accessing information with NAND flash memory. The NAND Flash memory can include single-level cell (SLC), multi-level cell (MLC), triple-level cell (TLC), quad-level cell (QLC), or the like. However, it is understood that the storage system 100 can utilize the error correction mechanism with other types of memory, such as resistive non-volatile memory, other types of flash or non-volatile memory, or a combination thereof.

It is understood that the embodiment discussed above is used to describe one embodiment and other embodiments are possible. Another possible embodiment can integrate the control processor 110, the read/write channel 104, the system interface 106, the non-volatile memory array 102, or a combination thereof into a single circuit.

It has been discovered that the control processor 110 can proactively map the optimal read threshold set 128 for the sector 0 116 through sector N 118 in the physical block 114. This can allow the ER circuitry 124 to calculate the level change statistics 126 for further monitoring the read reliability of the sector 0 116 through sector N 118 and make proactive adjustments to the read threshold 122 for reading the rest of the user data 108 stored in the physical block 114.

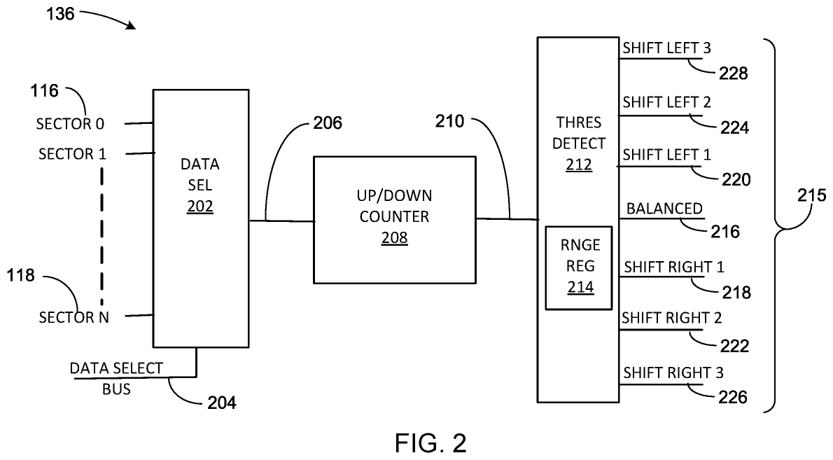

Referring now to FIG. 2, therein is a functional block diagram of a 1 and 0 counter 136 in an embodiment. The functional block diagram of a 1 and 0 counter 136 depicts the sector 0 116 through sector N 118 coupled to a data selector 202. The data selector 202 can be a hardware multiplexer controlled by the control processor 110 of FIG. 1 through a data select bus 204. The data selector 202 can pass the user data 108 of FIG. 1 present on the input coupled to the sector 0 116 through sector N 118 based on the address of the data select bus 204.

A selected channel data 206, output from the data selector 202, can be input to an up/down counter 208. The up/down counter 208 can be a hardware structure that can increment or decrement based on a data bit detected as a 0 or 1 respectively. It would be understood that a correctly read one of the sector 0 116 through sector N 118 would result in the counter ending at a count of zero because there are the same number of 1's and 0's in the selected channel data 206. When the selected channel data 206 does not contain the same number of 1's and 0's, the up/down counter 208 will indicate a residual count 210 that is not equal to zero.

It is understood that the detection of the uncorrectable error 132 of FIG. 1 indicates that there are more error bits in the selected one of the sector 0 116 through sector N 118 than can be corrected by ER circuitry 124 of FIG. 1 performing error correction of the selected channel data 206 without additional information. During the error recovery process, the control processor 110 of FIG. 1 can adjust the read threshold 122 of FIG. 1 in order to increase the possibility of correcting the user data 108 presented on the selected channel data 206. In some cases, the adjustment of the read threshold 122 will not improve the likelihood of correcting the user data 108 presented on the selected channel data 206. In this event, other means must be employed to correct the user data 108.

The residual count 210 can be an indication that the read threshold 122 used to access the user data 108 might have produced an offset in the number of 1's and 0's in the sector being read. The residual count 210 can be coupled to a threshold detector 212 that can categorize the difference between the number of 1's and 0's in the user data 108. When the residual count 210, representing the difference in the count of 0's and the count of 1's, is compared in the range register 214, to provide an indication of an adjustment that can be made to the optimal read threshold set 128 of FIG. 1 and the read threshold 122 in order to mitigate errors in the sector 0 116 through sector N 118 within the physical block 114.

The residual count 210 can be an indicator of the type of adjustment required to mitigate errors in the physical block 114. The residual count 210 can be compared to the value contained in the range register 214. The threshold detector 212 can identify threshold adjustment ranges 215 that can enable the update of the read threshold 122. The range register 214 can include upper and lower limits for each of the threshold adjustment ranges 215. The threshold adjustment ranges 215 can be configured by the control processor 110 to establish an appropriate response for adjusting the read threshold 122 based on the difference in the 1's and the 0's count represented by the residual count 210. The threshold adjustment ranges 215 can include a sector balanced 216, a shift right one 218, a shift left one, 220, a shift right two 222, a shift left two 224, a shift right three 226, and a shift left three 228.

Each of the threshold adjustment ranges 215 can represent a range of the residual count 210 indicating how much of a difference between the number of the 1's and the 0's was detected when the ER circuitry 124 was able to correct the uncorrectable error 132. The sector balanced 216 can indicate that there were a range between 20, representing 20 more 0's than the number of 1's, and −20, representing 20 more 1's than the number of 0's. Since the ER circuitry 124 is capable of correcting on the order to 256 error bits, the sector balanced 216 does not require an adjustment to the read threshold 122, but the value of the read threshold 122 used to correct the uncorrectable error 132 can be transferred to the optimal read threshold set 128.

The shift right one 218 can indicate a count of −21 to −40, more 1's than 0's, which allows the read threshold 122 to be adjusted by one count to the right, as an increase in the read threshold 122, prior to updating the optimal read threshold set 128. The shift left one 220 can indicate the count of 21 to 40, more 0's than 1's, which allows the read threshold 122 to be adjusted by one count to the left, as a decrease in the read threshold 122, prior to updating the optimal read threshold set 128.

The shift right two 222 can indicate a count of −41 to −60, more 1's than 0's, which allows the read threshold 122 to be adjusted by two counts to the right, as an increase in the read threshold 122, prior to updating the optimal read threshold set 128. The shift left two 224 can indicate the count of 41 to 60, more 0's than 1's, which allows the read threshold 122 to be adjusted by two count to the left, as a decrease in the read threshold 122, prior to updating the optimal read threshold set 128.

The shift right three 226 can indicate a count less than or equal to −61, more 1's than 0's, which allows the read threshold 122 to be adjusted by three counts to the right, as an increase in the read threshold 122, prior to updating the optimal read threshold set 128. The shift left three 228 can indicate the count greater than or equal to 61, more 0's than 1's, which allows the read threshold 122 to be adjusted by three count to the left, as a decrease in the read threshold 122, prior to updating the optimal read threshold set 128.

The ability to adjust the read threshold 122 prior to updating the optimal read threshold set 128 can proactively mitigate errors that would have otherwise been detected by reads of the sector 0 116 through the sector N 118 within the physical block 114. When the adjustment of the read threshold 122, based on the threshold adjustment ranges 215, can circumvent the error recovery processes in the rest of the physical block 114. The ability to read the rest of the physical block 114 without going through the error recovery process can significantly increase the performance of the storage system 100 of FIG. 1.

It has been discovered that the application of the 1 and 0 counter 136 can mitigate errors in the sector 0 116 through the sector N 118 once the error recovery process has completed and reduce the number of the read retries that are applied to the remainder of the sector 0 116 through the sector N 118 that would have been detected as the uncorrectable error 132. The resulting adjustments to the read threshold 122 that is updated to the optimal read threshold set 128 can improve the performance of the system host 107 of FIG. 1, while extending the useable life of the non-volatile storage array 102 of FIG. 1. The control processor 110 can update the adjustments to the read threshold 122 after any error, correctable or uncorrectable, in the user data 108. The update of the optimal read threshold set 128 allows a more accurate tracking of changes in the physical block 114 to provide the highest probability of reading the user data 108 without detecting the uncorrectable error 132.

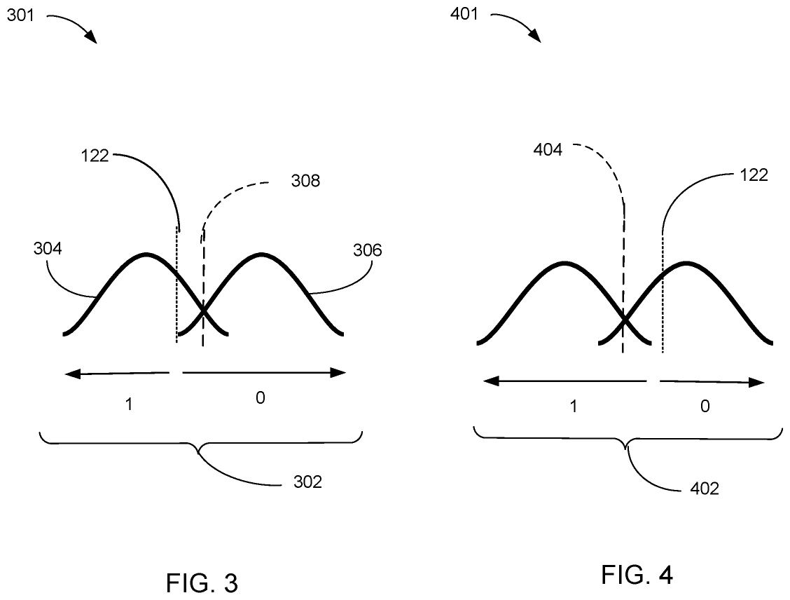

Referring now to FIG. 3, therein is shown a graphical view of an exemplary access 301 of a cell of the non-volatile storage array 102. The graphical view of an exemplary access 301 of the cell of the storage array 102 depicts a corrected data error 302 as read from the cell in the physical block 114 of FIG. 1. The read threshold 122 can be set by the control processor 110 of FIG. 1 based on the age and condition of the non-volatile storage array 102 of FIG. 1. The corrected data error 302 can have the read threshold 122 shifted from the optimal value. In the present embodiment, the value of the read threshold 122 can be adjusted to a more advantageous position before the read threshold 122 is added to the optimal read threshold set 128. The adjusting of the read threshold 122 based on the threshold adjustment ranges 215 can proactively mitigate the errors that would have been detected while reading the user data 108 from the physical block 114.

In the exemplary access 301 of a cell of the non-volatile storage array 102, the control processor 110 can sample the threshold adjustment ranges 215 in order to determine what amount of adjustment should be applied to the further accesses of the physical block 114. Since the read threshold 122 is skewed to the left during processing of the corrected error 302, the control processor 110 can find the shift right 3 226 of FIG. 2 activated based on the difference in count of 1's 304 and 0's 306. By adjusting the read threshold 122 to a position three counts to the right an adjusted threshold 308 can be correctly positioned for further reads of the user data 108 from the physical block 114.

It has been discovered that the control processor 110 can sample the threshold adjustment ranges 215 in order to mitigate errors in the physical block 114. By calculating the adjusted threshold 308 before updating the optimal read threshold set 128, the user data 108 can be read from the physical block 114 with few or none of the corrected error 302 or the uncorrectable error 132 detected because the threshold has been adjusted to the optimal value for the rest of the physical block 114.

Referring now to FIG. 4, therein is shown a graphical view of an exemplary access 401 of a cell of the non-volatile storage array 102. The graphical view of an exemplary access 401 of the cell of the storage array 102 depicts a corrected data error 302 as read from the cell in the physical block 114 of FIG. 1. The read threshold 122 can be set by the control processor 110 of FIG. 1 based on the age and condition of the non-volatile storage array 102 of FIG. 1. The corrected data error 402 can have the read threshold 122 shifted from the optimal value. In the present embodiment, the value of the read threshold 122 can be adjusted to a more advantageous position before the read threshold 122 is added to the optimal read threshold set 128. The adjusting of the read threshold 122 based on the threshold adjustment ranges 215 can proactively mitigate the errors that would have been detected while reading the user data 108 from the physical block 114.

In the exemplary access 401 of a cell of the non-volatile storage array 102, the control processor 110 can sample the threshold adjustment ranges 215 in order to determine what amount of adjustment should be applied to the further accesses of the physical block 114. Since the read threshold 122 is skewed to the right during processing of the corrected error 402, the control processor 110 can find the shift left 3 228 of FIG. 2 activated based on the difference in count of the 1's and the 0's. By adjusting the read threshold 122 to a position three counts to the left an adjusted threshold 404 can be correctly positioned for further reads of the user data 108 from the physical block 114.

It has been discovered that the control processor 110 can sample the threshold adjustment ranges 215 in order to mitigate errors in the physical block 114. By calculating the adjusted threshold 404 before updating the optimal read threshold set 128, the user data 108 can be read from the physical block 114 with few or none of the corrected error 402 or the uncorrectable error 132 detected because the threshold has been adjusted to the optimal value for the rest of the physical block 114.

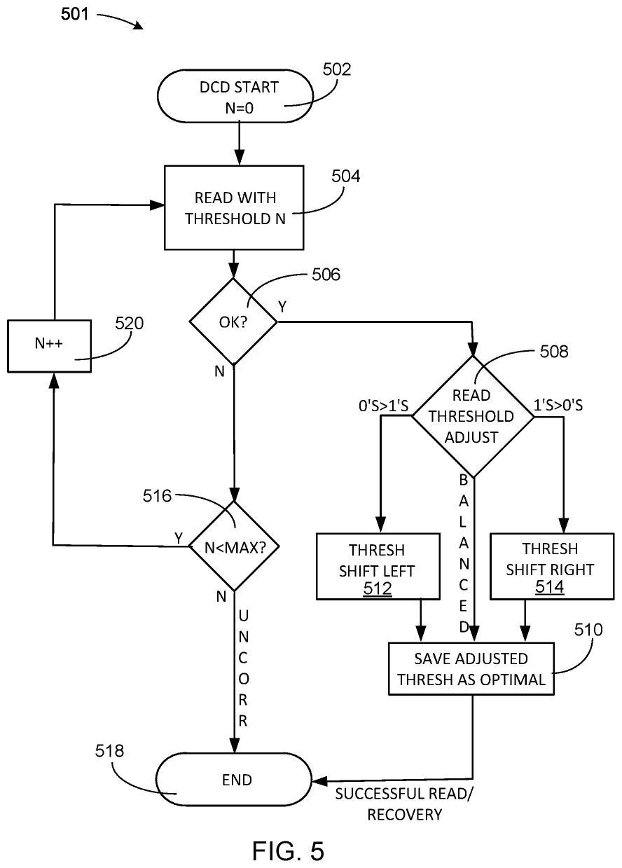

Referring now to FIG. 5, therein is shown an operational flow diagram 501 of the storage system 100 with error recovery mechanism in an embodiment of the present invention. It is understood that the functions described in this application can be implemented as instructions stored on a non-transitory computer readable medium to be executed by a host processor (not shown), the control processor unit 110 of FIG. 1, a math co-processor, a processor core, or a combination thereof.

The non-transitory computer readable medium can include compact disk (CD), digital video disk (DVD), or universal serial bus (USB) flash memory devices. The non-transitory computer readable medium can be integrated as a part of a host system not shown or installed as non-volatile memory array 102 of the storage system 100.

The non-transitory computer readable medium can include instructions required to perform the operations of a decode start with initial threshold 502. The first selection of the read threshold 122 of FIG. 1 can be the default threshold 404 of FIG. 4. The user data 108 of FIG. 1 read with the initial value of the read threshold 122 can be a baseline for further analysis.

The flow can include a read user data with a current read threshold 504, in which the control processor 110 of FIG. 1 can configure the read/write circuitry 120 of FIG. 1 to access the user data 108 using the current value of the read threshold 122.

The flow includes a check for data OK 506, the control processor 110 can monitor the occurrence of any of the correctable error 302 of FIG. 3 or the uncorrectable error 132 of FIG. 1 in the user data 108. The control processor 110 can configure the error recovery circuitry 124 of FIG. 1 to correct any of the correctable errors 302 on-the-fly with no further reading of the user data 108. The flow proceeds to a read threshold adjustments 508 where the control processor 110 can access the 1 and 0 counter 136 of FIG. 1 to determine whether the user data 108 has a disparity in the number of 1's and 0's in the sector. It is understood that the user data 108 has been written with an equal number of the 1's 304 of FIG. 3 and the 0's 306 of FIG. 3. As the cells of the physical block 114 age, some of the data in the cells can shift and be mis-read. The control processor 110 can load the range register 214 in the 1 and 0 counter 136 that can activate the detection of the threshold adjustment ranges 215 of FIG. 2. If the sector balanced 216 is active, the number of 1's and 0's is within the range established by the control processor 110 loading the range register 214. When the sector balanced 216 is activated, the flow can proceed to a save adjusted threshold as optimal 510 without making any further adjustments to the read threshold 122. The sector balanced 216 indicates that the read threshold 122 is appropriate for further reading of the user data 108.

If the read threshold adjustments 508 determines that the number of the 1's 304 of FIG. 3 and the 0's 306 of FIG. 3 is not balanced, the control processor 110 can determine which of the threshold adjustment ranges 215 is activated. If the number of 0's 306 is greater than the number of 1's 304, as indicated by the shift left 1 220 of FIG. 2, the shift left 2 224 of FIG. 2, or the shift left 3 228 of FIG. 2, the flow proceeds to a threshold shift left 512. The control processor 110 can adjust the read threshold 122 based on the magnitude indicated by the threshold adjustment ranges 215. The flow then proceeds to the save adjusted threshold as optimal 510 to save the adjusted read threshold 404 of FIG. 4 in the optimal read threshold set 128. It is understood that the control processor 110 can save the adjusted read threshold 404 after every successful read or error recovery.

If the read threshold adjustments 508 determines that the number of the 1's 304 and the 0's 306 is not balanced, the control processor 110 can determine which of the threshold adjustment ranges 215 is activated. If the number of 1's is greater than the number of 0's, as indicated by the shift right 1 218 of FIG. 2, the shift right 2 222 of FIG. 2, or the shift right 3 226 of FIG. 2, the flow proceeds to a threshold shift right 514. The control processor 110 can adjust the read threshold 122 based on the magnitude indicated by the threshold adjustment ranges 215. The flow then proceeds to the save adjusted threshold as optimal 510 to save the adjusted read threshold 404 of FIG. 4 in the optimal read threshold set 128.

The flow proceeds from the save adjusted threshold as optimal 510 to the end 518 to complete the read processing.

If the check for data OK 506 determines that the user data 108 is not OK, the flow proceeds to threshold less than maximum 516. If all of the thresholds have been attempted while the data error remains and the threshold is equal to the maximum, the uncorrectable error 132 is declared and the flow proceeds to the end 518 to complete the read processing. Alternatively, if the current value of the read threshold 122 is less than the maximum allowable value of the read threshold 122, the flow proceeds to an increment threshold 520 for another attempt at correctly reading the user data 108.

It has been discovered that the storage system 100 can increase performance of the non-volatile storage array 102 when accessing the user data 108. The updating of the optimal read threshold set 128, based on the threshold adjustment ranges 215, can minimize the likelihood of detecting the uncorrectable error 132 of FIG. 1 when reading the sector 0 116 through the sector N 118 of the physical block 114. Each of the physical block 114 in the non-volatile storage array 102 can have a different set of values for the optimal read threshold set 128. When the optimal read threshold set 128 activates the sector balanced 216 or correctly read the user data 108, the processing can be complete and the data recovered through the last used of the read threshold 122. While the user data 108 being read is corrected using the read threshold 122, the control processor 110 can perform adjustments to generate the adjusted read threshold 304 of FIG. 3 based on the threshold adjustment ranges 215 prior to updating the optimal read threshold set 128. This process can significantly reduce the likelihood of detecting the uncorrectable error 132 while reading the remainder of the user data 108 in the physical block 114.

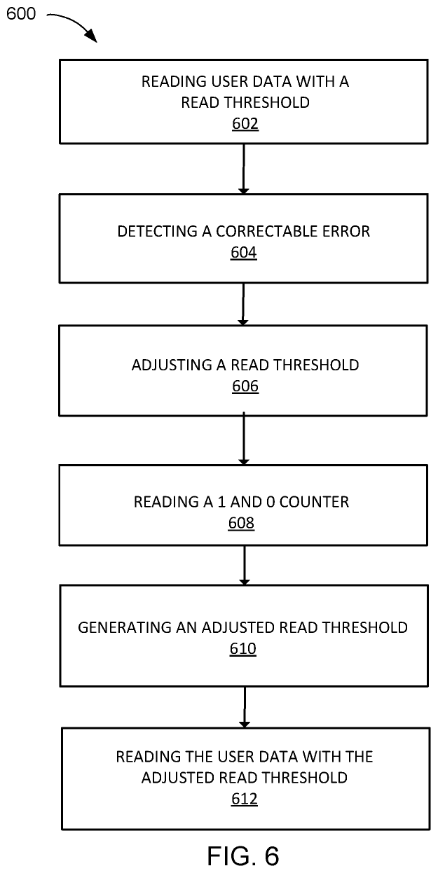

Referring now to FIG. 6, therein is shown a flow chart of a method 600 of operation of a storage system 100 in an embodiment of the present invention. The method 600 includes: reading user data from a non-volatile memory array using a read threshold in a block 602; detecting a correctable data error in the user data, in a block 604; adjusting the read threshold to correct the correctable data error, in a block 606; reading a 1 and 0 counter for determining which threshold adjustment range has been activated, in a block 608; generating an adjusted read threshold, based on the threshold adjustment range, for updating an optimal read threshold set, in a block 610; and reading the user data in a physical block using the adjusted read threshold, in a block 612.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level. While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. A storage system comprising:
a control processor, configured to:
read user data with a read threshold,
detect a correctable data error in the user data,
adjust the read threshold to correct the correctable data error,
read a 1 and 0 counter to determine which threshold adjustment range has been activated,
generate an adjusted read threshold, based on the threshold adjustment range, to update an optimal read threshold set; and
read the user data in a physical block using the adjusted read threshold.

2. The system as claimed in claim 1 wherein the control processor is further configured to interpret a residual count of 1's and 0's based on the values loaded in a range register.

3. The system as claimed in claim 1 wherein the control processor is further configured to update the optimal read threshold set with the read threshold when the control processor detects a sector balanced.

4. The system as claimed in claim 1 wherein the control processor is further configured to read the user data in the physical block using the adjusted read threshold from the optimal read threshold set.

5. The system as claimed in claim 1 wherein the control processor is further configured to determine the adjusted read threshold by reading a shift left 1, a shift left 2, and a shift left 3, when the number of 0's is greater than the number of 1's.

6. The system as claimed in claim 1 wherein the control processor is further configured to determine the adjusted read threshold by reading a shift right 1, a shift right 2, and a shift right 3, when the number of 0's is less than the number of 1's.

7. The system as claimed in claim 1 wherein the control processor is configured to mitigate the correctable error when reading the physical block by using the adjusted read threshold.

8. A method of operation of a storage system comprising:
reading user data from a non-volatile memory array using a read threshold;
detecting a correctable data error in the user data;
adjusting the read threshold to correct the correctable data error;
reading a 1 and 0 counter for determining which threshold adjustment range has been activated;
generating an adjusted read threshold, based on the threshold adjustment range, for updating an optimal read threshold set; and
reading the user data in a physical block using the adjusted read threshold.

9. The method as claimed in claim 8 further comprising interpreting a residual count of 1's and 0's based on the values loaded in a range register.

10. The method as claimed in claim 8 further comprising updating the optimal read threshold set with the read threshold when the control processor detects a sector balanced.

11. The method as claimed in claim 8 further comprising reading the user data in the physical block using the adjusted read threshold from the optimal read threshold set.

12. The method as claimed in claim 8 further comprising determining the adjusted read threshold by reading a shift left 1, a shift left 2, and a shift left 3, when the number of 0's is greater than the number of 1's.

13. The method as claimed in claim 8 further comprising determining the adjusted read threshold by reading a shift right 1, a shift right 2, and a shift right 3, when the number of 0's is less than the number of 1's.

14. The method as claimed in claim 8 further comprising mitigating the correctable error when reading the physical block by using the adjusted read threshold.

15. A non-transitory computer readable medium including instructions for execution, the medium comprising:
reading user data from a non-volatile memory array using a read threshold;
detecting a correctable data error in the user data;
adjusting the read threshold to correct the correctable data error;
reading a 1 and 0 counter for determining which threshold adjustment range has been activated;
generating an adjusted read threshold, based on the threshold adjustment range, for updating an optimal read threshold set; and
reading the user data in a physical block using the adjusted read threshold.

16. The medium as claimed in claim 15 further comprising interpreting a residual count of 1's and 0's based on the values loaded in a range register.

17. The medium as claimed in claim 15 further comprising updating the optimal read threshold set with the read threshold when the control processor detects a sector balanced.

18. The medium as claimed in claim 15 further comprising reading the user data in the physical block using the adjusted read threshold from the optimal read threshold set.

19. The medium as claimed in claim 15 further comprising determining the adjusted read threshold by reading a shift left 1, a shift left 2, and a shift left 3, when the number of 0's is greater than the number of 1's.

20. The medium as claimed in claim 15 further comprising determining the adjusted read threshold by reading a shift right 1, a shift right 2, and a shift right 3, when the number of 0's is less than the number of 1's.
